(19) United States
(12) Patent Application Publication
(10) Pub. No.: US 2016/0079369 A1
(43) Pub. Date: Mar. 17, 2016

(54) SEMICONDUCTOR DEVICE

(71) Applicant: Kabushiki Kaisha Toshiba, Tokyo (JP)

(72) Inventors: Tsuneo Ogura, Kamakura Kanagawa (JP); Shinichiro Misu, Machida Tokyo (JP); Tomoko Matsudai, Shibuya Tokyo (JP)

(21) Appl. No.: 14/843,252

(22) Filed: Sep. 2, 2015

(30) Foreign Application Priority Data
Sep. 11, 2014 (JP) 2014-185432

(51) Int. Cl. H01L 29/10; H01L 29/868; H01L 27/06; H01L 29/739

(52) U.S. Cl. CPC H01L 29/1095; H01L 29/7395; H01L 29/868; H01L 27/0664

(57) ABSTRACT

According to one embodiment, a semiconductor device includes first and second electrodes, and a first semiconductor region provided between the first and second electrodes. A first element region includes a second semiconductor region provided between the first semiconductor region and the first electrode, a third semiconductor region provided between the first semiconductor region and the second electrode, a fourth semiconductor region provided between the third semiconductor region and the second electrode, and a third electrode provided in the first, third and fourth semiconductor regions. A second element region includes a fifth semiconductor region provided between the first semiconductor region and the first electrode, and a sixth semiconductor region provided between the first semiconductor region and the second electrode. An isolation region includes a seventh semiconductor region provided between the first semiconductor region and the second electrode. The isolation region is positioned between the first and second element regions.

### CROSS-REFERENCE TO RELATED APPLICATIONS

This application is based upon and claims the benefit of priority from Japanese Patent Application No. 2014-185432, filed on Sep. 11, 2014; the entire contents of which are incorporated herein by reference.

### FIELD

Embodiments described herein relate generally to a semiconductor device.

### BACKGROUND

There is a reverse conducting IGBT (Insulated Gate Bipolar Transistor) as a semiconductor device served as both an IGBT and a diode. In the reverse conducting IGBT, a part of a p-type collector region is replaced by an n-type region, and the n-type region functions as a cathode region of the diode.

However, in the reverse conducting IGBT, since hole injection is increased by impurity elements introduced into a p-type base region of the IGBT, an increase in switching speed of the diode may become difficult.

### BRIEF DESCRIPTION OF THE DRAWINGS

FIG. 1A is a schematic sectional view showing a semiconductor device of a first embodiment, and FIG. 1B is a schematic plan view showing the semiconductor device of the first embodiment;

FIG. 2A and FIG. 2B are schematic sectional views showing an ON state of the semiconductor device of the first embodiment;

FIG. 3A and FIG. 3B are schematic sectional views showing recovery states of the FWD region of the semiconductor device of the first embodiment;

FIG. 4A and FIG. 4B are schematic sectional views showing an operation of a semiconductor device according to a first reference example;

FIG. 5A and FIG. 5B are schematic sectional views showing an operation of a semiconductor device according to a second reference example;

FIG. 6A and FIG. 6B are schematic sectional views showing an operation of the semiconductor device of the first embodiment;

FIG. 7A is a graph showing an example of the simulation result of the carrier density at recovery in the semiconductor device, and FIG. 7B to FIG. 7D show models of the semiconductor devices used for the simulation shown in FIG. 7A;

FIG. 8 is a schematic sectional view showing a semiconductor device of a second embodiment;

FIG. 9 is a schematic sectional view showing a semiconductor device of a third embodiment;

FIG. 10 is a schematic sectional view showing a semiconductor device of a fourth embodiment;

FIG. 11 is a schematic sectional view showing a semiconductor device of a fifth embodiment;

FIG. 12 is a schematic sectional view showing a semiconductor device of a sixth embodiment; and

FIG. 13 is a schematic sectional view showing a semiconductor device of a seventh embodiment.

### DETAILED DESCRIPTION

According to one embodiment, a semiconductor device includes a first electrode, a second electrode, and a first semiconductor region of a first conductivity-type provided between the first electrode and the second electrode. A first element region includes a second semiconductor region of a second conductivity-type provided between the first semiconductor region and the first electrode, a third semiconductor region of the second conductivity-type provided between the first semiconductor region and the second electrode, a fourth semiconductor region of the first conductivity-type provided between the third semiconductor region and the second electrode, and a third electrode provided in the first semiconductor region, the third semiconductor region and the fourth semiconductor region via a first insulating film. A second element region includes a fifth semiconductor region of the first conductivity-type provided between the first semiconductor region and the first electrode and having a higher impurity concentration than the first semiconductor region, and a sixth semiconductor region of the second conductivity-type provided between the first semiconductor region and the second electrode. An isolation region includes a seventh semiconductor region of the second conductivity-type provided between the first semiconductor region and the second electrode, and is in contact with the second electrode. The isolation region is positioned between the first element region and the second element region.

Various embodiments will be described hereinafter with reference to the accompanying drawings. In the following description, the same components are denoted by the same reference numerals, and a description of components once described is appropriately omitted. Besides, in the embodiments, unless otherwise stated, an n-type (first conductivity-type) impurity concentration becomes low in order of n⁺-type, n-type and n⁻-type. Besides, a p-type (second conductivity-type) impurity concentration becomes low in order of p⁺-type and p-type.

### First Embodiment

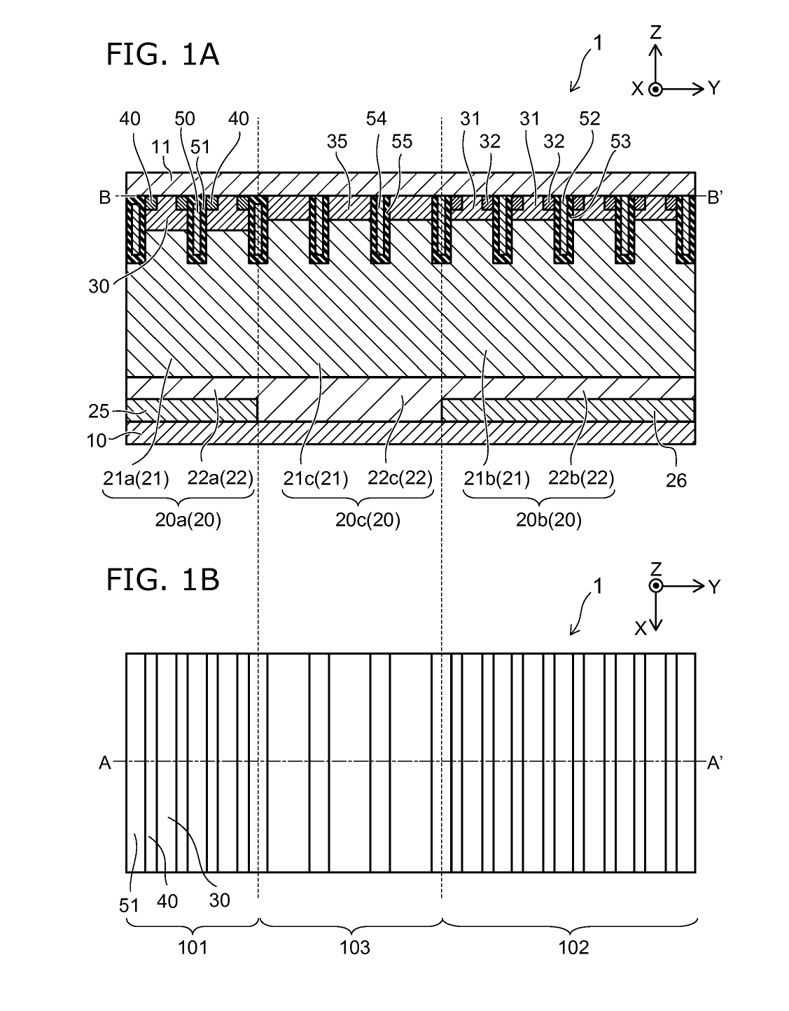

FIG. 1A is a schematic sectional view showing a semiconductor device of a first embodiment, and FIG. 1B is a schematic plan view showing the semiconductor device of the first embodiment.

FIG. 1A shows a section along line A-A′ of FIG. 1B, and FIG. 1B shows a state where a section along line B-B′ of FIG. 1A is seen from above. Besides, in the following drawings, a three-dimensional coordinate (XYZ coordinate system) is introduced to represent directions of the semiconductor device.

A semiconductor device 1 of the first embodiment is a semiconductor device having an upper and lower electrode structure. The semiconductor device 1 includes an electrode 10 (first electrode), an electrode 11 (second electrode), an IGBT region 101 (first element region), a FWD (Free Wheeling Diode) region 102 (second element region), and an isolation region 103. In the semiconductor device 1, the IGBT region 101 as a transistor and the FWD region 102 as a freewheel diode are not in direct contact with each other, but the isolation region 103 is provided between these regions.

In the semiconductor device 1, an n⁻-type semiconductor region 21 and an n-type semiconductor region 22 are provided between the electrode 10 and the electrode 11. The n-type semiconductor region 22 is positioned between the electrode 10 and the n⁻-type semiconductor region 21. The impurity concentration of the semiconductor region 22 is higher than the impurity concentration of the semiconductor region 21.

The semiconductor region 21 is arranged to be shared by the IGBT region 101, the FWD region 102 and the isolation region 103. The semiconductor region 21 includes a portion 21a provided in the IGBT region 101, a portion 21b provided in the FWD region 102, and a portion 21c provided in the isolation region 103.

The semiconductor region 22 is arranged to be shared by the IGBT region 101, the FWD region 102 and the isolation region 103. The semiconductor region 22 includes a portion 22a provided in the IGBT region 101, a portion 22b provided in the FWD region 102, and a portion 22c provided in the isolation region 103. In the embodiment, the semiconductor region 21 and the semiconductor region 22, which have the same conductivity, are collectively called a semiconductor region 20 (first semiconductor region).

Accordingly, the portion 21a of the semiconductor region 21 and the portion 22a of the semiconductor region 22 are a first portion 20a of the semiconductor region 20. The portion 21b of the semiconductor region 21 and the portion 22b of the semiconductor region 22 are a second portion 20b of the semiconductor region 20. The portion 21c of the semiconductor region 21 and the portion 22c of the semiconductor region 22 are a third portion 20c of the semiconductor region 20.

First, the IGBT region 101 will be described.

In the IGBT region 101, a p⁺-type collector region 25 (second semiconductor region) is provided between the first portion 20a of the semiconductor region 20 and the electrode 10. The collector region 25 is in contact with the electrode 10.

A p-type base region 30 (third semiconductor region) is provided between the first portion 20a of the semiconductor region 20 and the electrode 11. An n⁺-type emitter region 40 (fourth semiconductor region) is selectively provided between the base region 30 and the electrode 11. The emitter region 40 extends in the X-direction. The base region 30 and the emitter region 40 are in contact with the electrode 11.

Furthermore, in the IGBT region 101, the portion 21a of the semiconductor region 21 may be replaced with the n⁻-type base region 21a, the portion 22a of the semiconductor region 22 may be replaced with the buffer region 22a, the electrode 10 may be replaced with the collector electrode 10, and the electrode 11 may be replaced with the emitter electrode 11.

Furthermore, a gate electrode 50 (third electrode) is in contact with the first portion 20a of the semiconductor region 20, the base region 30 and the emitter region 40 via a gate insulating film 51 (first insulating film). The gate electrode 50 extends from the electrode 11 side to the electrode 10 side and extends in the X-direction. The plural gate electrodes 50 are respectively arranged in the Y-direction. Although the structure of the gate electrode 50 shown in FIG. 1A is a so-called trench gate structure, the structure may be of a planar type.

As stated above, the IGBT including the emitter electrode, the n⁺-type emitter region, the p-type base region, the n-type base region, the p⁺-type collector region, the collector electrode and the gate electrode is provided in the IGBT region 101.

Next, the FWD region 102 will be described.

In the FWD region 102, the second portion 20b of the semiconductor region 20 is provided between the electrode 10 and the electrode 11. An n⁺-type cathode region 26 (fifth semiconductor region) is provided between the second portion 20b of the semiconductor region 20 and the electrode 10. The cathode region 26 is in contact with the electrode 10. The cathode region 26 is in ohmic contact with the electrode 10. The impurity concentration of the cathode region 26 is higher than the impurity concentration of the semiconductor region 20.

A p-type anode region 31 (sixth semiconductor region) is provided between the second portion 20b of the semiconductor region 20 and the electrode 11. The anode region 31 is in contact with the electrode 11. The anode region 31 is in Schottky contact with or in low-resistance contact with the electrode 11.

A p⁺-type anode region 32 (eighth semiconductor region) is selectively provided between the electrode 11 and the anode region 31. The anode region 32 extends in the X-direction. The plural anode regions 32 are respectively arranged in the Y-direction. The anode region 32 is in contact with the electrode 11. The anode region 32 is in ohmic contact with the electrode 11. The impurity concentration of the anode region 32 is higher than the impurity concentration of the anode region 31. Incidentally, the anode region 32 may be removed from the semiconductor device 1. For example, the embodiment includes also a structure in which the anode region 32 is removed from the structure shown in FIGS. 1A and 1B.

Furthermore, in the FWD region 102, the portion 22b of the semiconductor region 22 may be replaced with the cathode region 22b, the portion 21b of the semiconductor region 21 may be replaced with the intrinsic region 21b, the electrode 10 may be replaced with the cathode electrode 10, and the electrode 11 may be replaced with the anode electrode 11.

Furthermore, a connection region 52 (first connection region) contacting to the electrode 11 is provided in the FWD region 102. The connection region 52 is in contact with the second portion 20b of the semiconductor region 20, the anode region 31 and the anode region 32 via an insulating film 53 (second insulating film). The connection region 52 extends from the electrode 11 side to the electrode 10 side, and extends in the X-direction. The plural connection regions 52 are respectively arranged in the Y-direction.

As stated above, the PIN diode including the anode electrode, the anode region, the intrinsic region, the cathode region and the cathode electrode is provided in the FWD region 102.

Next, the isolation region 103 will be described.

In the isolation region 103, the third portion 20c of the semiconductor region 20 is provided between the electrode 10 and the electrode 11. The third portion 20c of the semiconductor region 20 is sandwiched between the first portion 20a of the semiconductor region 20 and the second portion 20b of the semiconductor region 20. The third portion 20c of the semiconductor region 20 is in contact with the electrode 10. For example, the portion 22c of the semiconductor region 20 is in Schottky contact with or in low-resistance contact with the electrode 10.

Furthermore, in the isolation region 103, a p-type semiconductor region 35 (seventh semiconductor region) is provided between the third portion 20c of the semiconductor region 20 and the electrode 11. The semiconductor region 35 is in contact with the electrode 11. The semiconductor region 35 is in Schottky contact with or in low-resistance contact with the electrode 11. The impurity concentration of the semiconductor region 35 may be lower than the impurity concentration of the anode region 31, or the impurity concentration of the semiconductor region 35 may be equal to the impurity concentration of the anode region 31. Besides, the impurity concentrations of the semiconductor region 35 and the anode region 31 are lower than the impurity concentration of the base region 30.

Furthermore, a connection region 54 (second connection region) contacting to the electrode 11 is provided in the isolation region 103. The connection region 54 is in contact with the third portion 20c of the semiconductor region 20 and the semiconductor region 35 via an insulating film 55 (third insulating film). The connection region 54 extends from the electrode 11 side to the electrode 10 side, and extends in the X-direction.

In the semiconductor device 1, the width of a set of the connection regions 54, the insulating films 55 and the semiconductor regions 35, which are arranged in the Y-direction, is substantially equal to the width of the portion 22c of the semiconductor region 22 sandwiched between the collector region 25 and the cathode region 26 in the Y-direction.

The main component of each of the plural semiconductor regions provided between the electrode 10 and the electrode 11 is, for example, silicon (Si). The main component of each of the plural semiconductor regions may be silicon carbide (SiC), gallium nitride (GaN) or the like. For example, phosphorous (P), arsenic (As) or the like is applied as an impurity element of a conductivity type such as n⁺-type, n-type or n⁻-type. For example, boron (B) or the like is applied as an impurity element of a conductivity type such as p⁺-type or p-type. Besides, even if the conductivity types of p-type and n-type are exchanged in the semiconductor device 1, the same effects can be obtained.

The material of the electrode 10 and the material of the electrode 11 are, for example, metal including at least one selected from a group including aluminum (Al), titanium (Ti), nickel (Ni), tungsten (W) and gold (Au). The materials of the gate electrode 50 and the connection regions 52 and 54 include, for example, polysilicon. Besides, the material of the insulating film includes, for example, silicon oxide or silicon nitride.

The operation of the semiconductor device 1 of the first embodiment will be described.

First, the operation of the IGBT region 101 and the FWD region 102 of the semiconductor device 1 will be described.

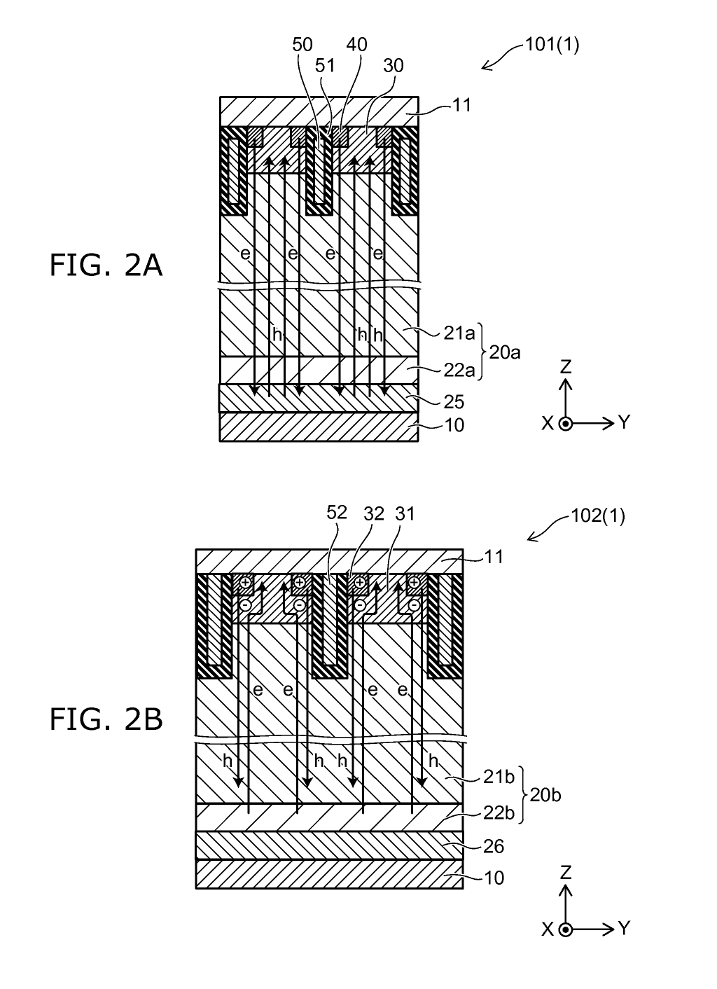

FIG. 2A and FIG. 2B are schematic sectional views showing an ON state of the semiconductor device of the first embodiment.

FIG. 2A shows an ON state of the IGBT region 101, and FIG. 2B shows an ON state of the FWD region 102. Incidentally, in FIGS. 2A and 2B, a case is supposed in which the semiconductor device 1 is included in an inverter circuit or the like.

First, the operation of the IGBT region 101 will be described (FIG. 2A).

A high potential is applied to the electrode 10 (collector electrode) rather than the electrode 11 (emitter electrode), and a potential not lower than a threshold voltage (Vth) is supplied to the gate electrode 50. In this case, a channel region is formed in the base region 30 along the gate insulating film 51, and the IGBT becomes in the ON state. That is, an electron current (e) flows from the emitter region 40 in order of the channel region, the base region 21a, the buffer region 22a and the collector region 25. A hole current (h) flows from the collector region 25 in order of the buffer region 22a, the base region 21a and the base region 30.

Incidentally, when the high potential is applied to the electrode 10 rather than the electrode 11, a reverse bias voltage is applied to the PIN diode of the FWD region 102. Thus, current does not flow through the FWD region 102.

The operation of the FWD region 102 will be described (FIG. 2B).

In general, a regenerative current flows in the PIN diode of the FWD region 102 immediately before the IGBT is turned on. That is, the PIN diode operates as a freewheel diode. While the freewheel diode operates, a forward bias voltage is temporarily applied between the cathode and the anode.

Here, the cathode region 26 is in ohmic contact with the electrode 10 (cathode electrode). Accordingly, an electron current (e) reaches the anode region 31 from the cathode region 26 through the second portion 20b of the semiconductor region 20.

For example, the p-type anode region 31 is in resistive contact with or in Schottky contact with the anode electrode 11. When the p-type anode region 31 is in Schottky contact with the anode electrode 11, although a junction between the anode region 31 and the anode electrode 11 (anode electrode) becomes an energy barrier for holes, the junction is not an energy barrier for electrons.

Accordingly, electrons flow from the cathode region 26 into the electrode 11 (anode region) through the second portion 20b of the semiconductor region 20 and the anode region 31. Thus, an electron current (e) is formed between the cathode and the anode.

However, a junction between the anode region 32 of the p-type high concentration region and the anode region 31 of the p-type low concentration layer becomes an energy barrier for electrons. Accordingly, the electrons, which flow up to the anode region 31 directly below the anode region 32, become hard to flow into the anode region 32.

Thus, when the electrons flow in the direction from the cathode side to the anode side and reach the vicinity of the anode region 32, the electrons move under the anode region 32 in a lateral direction, that is, in a direction substantially parallel to the Y-direction.

By the movement of the electrons, the anode region 32 contacting to the electrode 11 (anode electrode) becomes a positive electrode, and the anode region 31 positioned under the anode region 32 becomes a negative electrode relative to the anode region 32.

By the bias between the positive and negative electrodes, the energy barrier for holes between the anode region 31 and the anode region 32 becomes low under the anode region 32. Thus, holes are injected from the anode region 32 to the anode region 31. The injected holes constitute a hole current (h).

The hole current (h) increases as the width of the anode region 32 in the Y-direction or the contact area between the anode region 32 and the electrode 11 (anode electrode) becomes large. In other words, the injection amount of holes from the anode side is adjusted by the width or the contact area.

As stated above, in the FWD region 102, holes flow from the anode side to the cathode side in the ON state, and electrons flow from the cathode side to the anode side. Here, at the anode side, although holes are injected from the high-concentration anode region 32, the injection amount of holes from the low-concentration anode region 31 is small. The anode region 31 mainly contributes to the discharge of electrons. Thus, the recovery speed increases in the PIN diode of the FWD region 102.

Especially, in the FWD region 102, there are a region where the anode region 32 is provided in the Y-direction and a region where the anode region 32 is not provided. Thus, the contact area between the anode region 32 and the electrode 11 (anode electrode) decreases. Thus, the injection amount of holes from the anode side is suppressed in the FWD region 102, and the recovery speed becomes high.

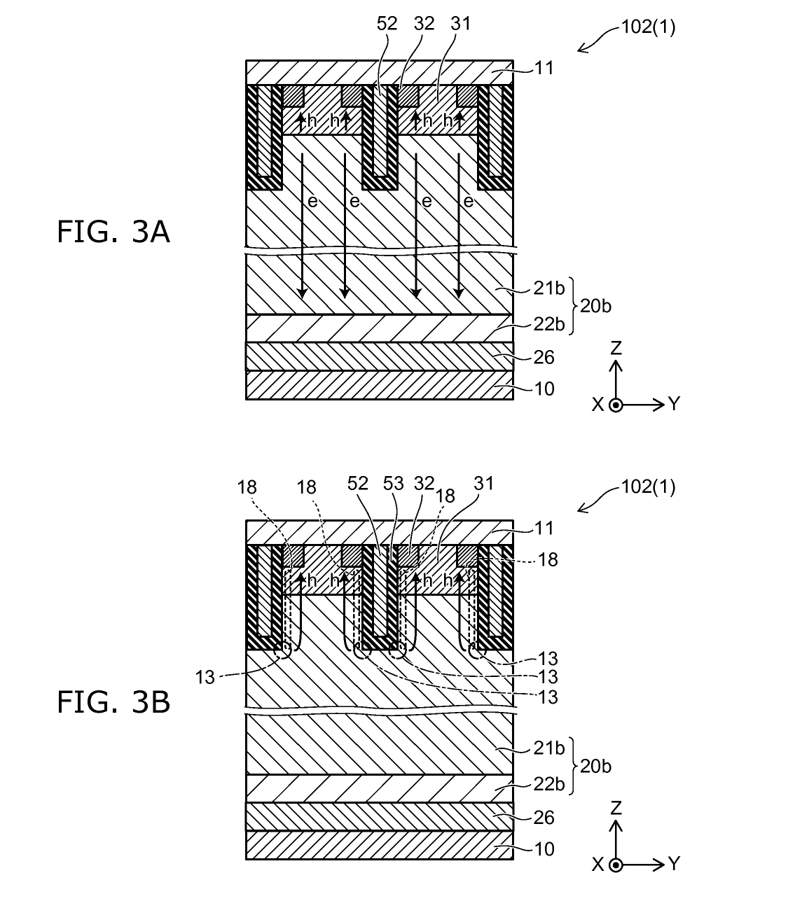

FIG. 3A and FIG. 3B are schematic sectional views showing recovery states of the FWD region of the semiconductor device of the first embodiment.

When the FWD region 102 is in the recovery state, the IGBT is in the off state.

FIG. 3A shows a state where a voltage between the anode and cathode is a reverse bias. That is, the voltage is applied between the cathode and anode, so that the electrode 11 (anode electrode) becomes a negative electrode, and the electrode 10 (cathode electrode) becomes a positive electrode.

When the reverse bias is applied between the anode and cathode from the state where a forward bias is applied between the anode and cathode, holes existing in the second portion 20b of the semiconductor region 20 move to the electrode 11 (anode electrode) side. Besides, electrons existing in the second portion 20b of the semiconductor region 20 move to the electrode 10 (cathode electrode) side.

When the reverse bias is applied, electrons flow into the electrode 10 (cathode electrode) through the cathode region 26, and holes flow into the electrode 11 (anode electrode) through the anode region 32.

At the recovery time, while the electron current (e) flows to the electrode 10 (cathode electrode) and the hole current (h) flows to the electrode 11 (anode electrode), a depletion layer extends to the second portion 20b of the semiconductor region 20 and the anode region 31 from the junction between the anode region 31 and the second portion 20b of the semiconductor region 20. Thus, the conduction between the electrode 11 (anode electrode) and the electrode 10 (cathode electrode) in the FWD region 102 is gradually blocked.

However, in the PIN diode, electric field concentration generally occurs at a place of a pn junction at recovery, and an avalanche may occur. In the first embodiment, damage caused by the avalanche is suppressed, and a safety operation range at recovery is enlarged.

FIG. 3B shows the recovery state of the FWD region 102.

For example, when a combination of the connection region 52 and the insulating film 53 is a trench region, the FWD region 102 includes a corner part 13 where a junction between the trench region and the second portion 20b of the semiconductor region 20 is sharply bent at a lower end of the trench region. An electric field is liable to be concentrated to the corner part 13 at recovery. Thus, the avalanche is liable to occur in the vicinity of the corner part 13. A flow of holes generated by the avalanche is called an avalanche current (h).

Here, the anode region 32 is in contact with the insulating film 53. That is, since the anode region 32 is positioned in the vicinity just above the corner part 13, the holes generated by the avalanche are discharged to the electrode 11 (anode electrode) through the anode region 32.

Furthermore, the plural corner parts 13 are provided in the FWD region 102. Since the avalanche is liable to occur in each of the plural corner parts 13 in the FWD region 102, places where the avalanche occur are dispersed. Accordingly, the avalanche current is also dispersed by the plural respective corner parts 13. The avalanche current is discharged to the electrode 11 (anode electrode) through each of the plural anode regions 32. Thus, breakdown strength of the semiconductor device 1 at recovery increases.

Furthermore, the avalanche current is preferentially discharged to the electrode 11 (anode electrode) through the anode region 32 in the FWD region 102. Thus, the injection of holes from the anode side can be further suppressed by further reducing the impurity concentration of the anode region 31.

Furthermore, since the same negative potential as the electrode 11 (anode electrode) is applied to the connection region 52 at recovery, an induced region 18 where the hole concentration increases is induced along the insulating film 53 in the anode region 31. The induced region 18 is a low resistance region for holes. That is, the efficiency of discharge of the holes to the electrode 11 (anode electrode) is further increased through the induced region 18 which is the low resistance region for the holes. Thus, the breakdown strength at recovery increases.

As described above, according to the semiconductor region 1 of the first embodiment, both increase in the recovery speed and increase in the breakdown strength at recovery are achieved, and the safety operation range is enlarged.

Before the operation of the semiconductor device 1 in which the isolation region 103 is provided is described, operations of semiconductor devices according to reference examples will be described.

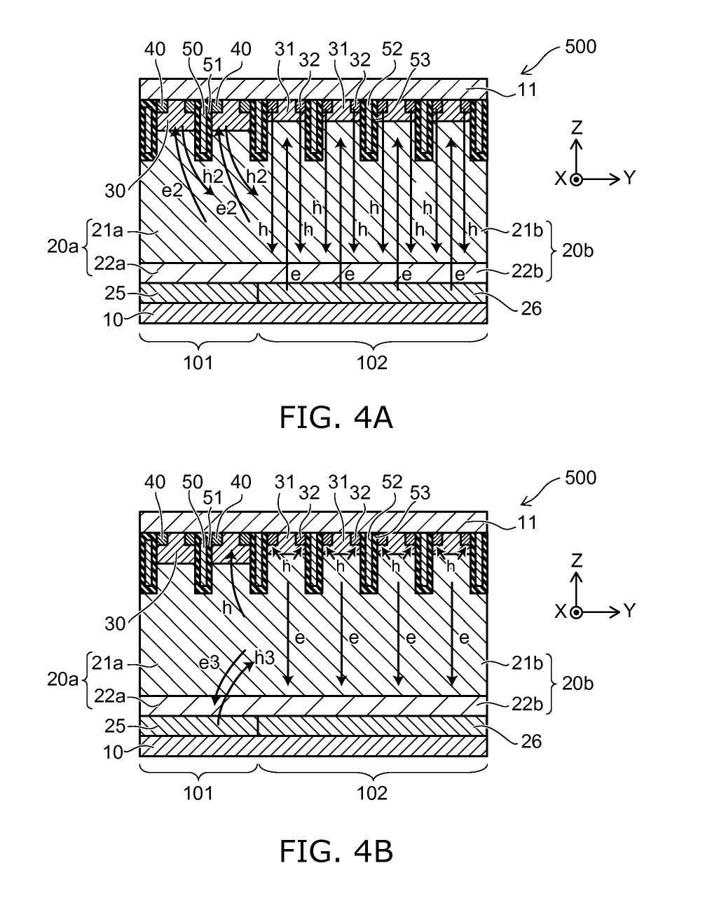

FIG. 4A and FIG. 4B are schematic sectional views showing an operation of a semiconductor device according to a first reference example.

In a semiconductor device 500 shown in FIG. 4A and FIG. 4B, the isolation region 103 is not provided. The semiconductor device 500 includes an IGBT region 101 and a FWD region 102, and the IGBT region 101 and the FWD region 102 are in direct contact with each other.

FIG. 4A shows a state where a PIN diode in the FWD region 102 is on. FIG. 4A shows the state where the PIN diode of the FWD region 102 functions as a freewheel diode. In this case, an electron current (e) flows from a cathode side to an anode side in the FWD region 102, and a hole current (h) flows from the anode side to the cathode side.

In this period, a state temporarily continues in which the potential of the electrode 11 is higher than the potential of the electrode 10. Here, the electrode 10 is shared by the IGBT region 101 and the FWD region 102, and the electrode 11 is shared by the IGBT region 101 and the FWD region 102.

Accordingly, a forward bias is applied also to a parasitic diode (p-type base region 30/n⁻-type base region 21a) of the IGBT region 101, and holes are injected from the p-type base region 30 to the n⁻-type base region 21a.

Furthermore, an n⁺-type cathode region 26 of a high concentration layer is adjacent to the collector region 25. And the IGBT region 101 and the FWD region 102 are in direct contact with each other. Thus, electrons (e2) discharged from the n⁺-type cathode region 26 diffuse up to the IGBT region 101

When the electrons diffused from the n⁺-type cathode region 26 to the IGBT region 101 go over the energy barrier of the parasitic diode (p-type base region 30/n⁻-type base region 21a), holes are injected from the p-type base region 30 to the n⁻-type base region 21a.

As stated above, holes may diffuse up to the FWD region 102. In FIG. 4A, the holes diffused from the p-type base region 30 to the FWD region 102 are denoted by holes (h2). Thus, the carrier diffuses to the IGBT region 101 when the PIN diode is conducted.

FIG. 4B shows a state where the PIN diode in the FWD region 102 is turned off. That is, the state is shown in which the reverse bias is applied to the PIN diode of the FWD region 102.

In this case, the voltage is applied between the cathode and the anode so that the electrode 11 (anode electrode) becomes a negative electrode, and the electrode 10 (cathode electrode) becomes a positive electrode. That is, in the FWD region 102, holes existing in the second portion 20b of the semiconductor region 20 move to the electrode 11 (anode electrode) side, and electrons existing in the second portion 20b of the semiconductor region 20 move to the electrode 10 (cathode electrode) side.

In this period, holes diffused from the FWD region 102 to the emitter side of the IGBT region 101 are discharged to the electrode 11 (emitter electrode) through the base region 30. However, electrons may diffuse from the FWD region 102 to the IGBT region 101 at the collector side of the IGBT region 101.

For example, when the diffused electrons (e3) go over the energy barrier between the p⁺-type collector region 25 and the n-type buffer region 22a, there is a possibility that holes are injected from the p⁺-type collector region 25 to the n-type buffer region 22a. And the injected holes diffuse up to the FWD region 102. In FIG. 4B, the holes diffusing from the p⁺-type collector region 25 to the FWD region 102 are denoted by holes (h3).

As stated above, in the semiconductor device 500, the carriers are liable to stay in the FWD region 102 before the recovery operation and after the recovery operation. Thus, an increase in recovery speed of the PIN diode is limited.

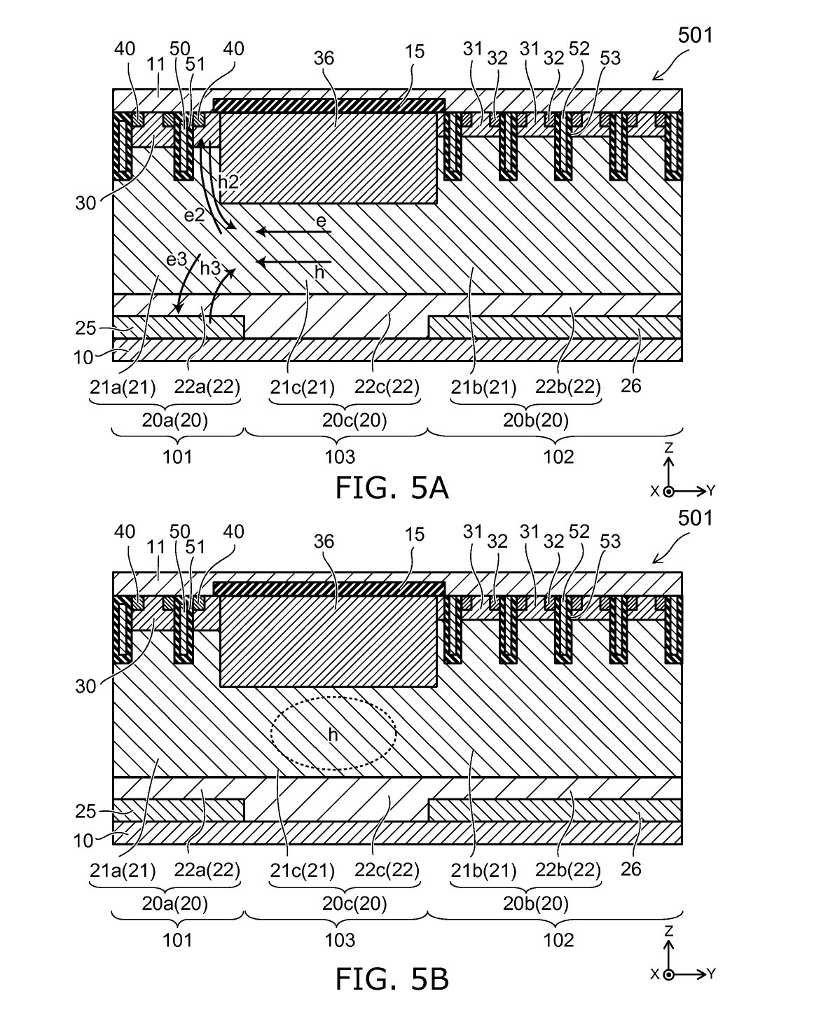

FIG. 5A and FIG. 5B are schematic sectional views showing an operation of a semiconductor device according to a second reference example.

A semiconductor device 501 shown in FIG. 5A includes an isolation region 103. A deep p⁺-type semiconductor region 36 is provided in the isolation region 103. The semiconductor region 36 extends from an electrode 11 side to an electrode 10 side. An insulating layer 15 is provided between the semiconductor region 36 and the electrode 11.

The semiconductor region 36 and the electrode 11 are electrically insulated from each other. At least a part of the semiconductor region 36 (for example, a part of a lower part of the semiconductor region 36) is in contact with a third portion 20c of a semiconductor region 20. The depth of the semiconductor region 36 is deeper than the depth of a gate insulating film 51 and the depth of an insulating film 53. Furthermore, a collector region 25 and a cathode region 26 are separated from each other through the isolation region 103.

The distance between an IGBT region 101 and a FWD region 102 becomes large by providing the isolation region 103. Accordingly, when a PIN diode in the FWD region 102 is in an ON state, electrons (e) and holes (h) flowing from the FWD region 102 to the IGBT region 101 become liable to disappear on the way.

Furthermore, since the distance between the IGBT region 101 and the FWD region 102 becomes large, electrons (e3) become hard to diffuse to the IGBT region 101 in the recovery state of the PIN diode, and holes (h3) become hard to be generated. Besides, even if the electrons (e3) move to the IGBT region 101 side, and the holes (h3) are generated, the holes (h3) flowing from the IGBT region 101 to the FWD region 102 become liable to disappear on the way.

Furthermore, an electric field concentrated to a junction between a p-type base region 30 and an n⁻-type base region 21a, an electric field concentrated to a junction between a p-type anode region 31 and an n⁻-type intrinsic region 21b, or an electric field concentrated to a lower end of the gate insulating film 51 and a lower end of the insulating film 53 is relaxed by providing the semiconductor region 36 deeper than the gate insulating film 51 and the insulating film 53 in the isolation region 103.

Furthermore, since the semiconductor region 36 and the electrode 11 are electrically insulated, holes become hard to be injected into the third portion 20c of the semiconductor region 20 from the semiconductor region 36.

However, since the semiconductor region 36 and the electrode 11 are electrically insulated, holes (h) stayed under the semiconductor region 36 become hard to be discharged to the electrode 11 side at the recovery of the PIN diode. For example, FIG. 5B shows a state where holes (h) stay under the semiconductor region 36 at the recovery. As stated above, also in the semiconductor device 501, an increase in recovery speed of the PIN diode is limited.

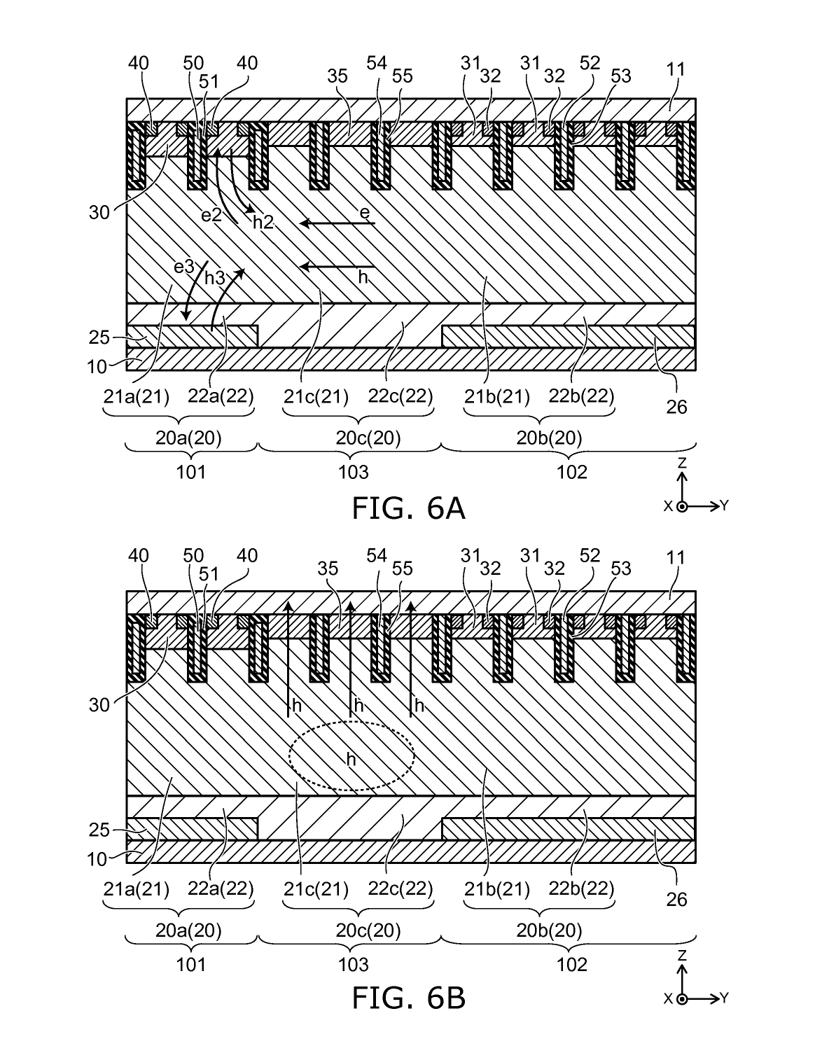

FIG. 6A and FIG. 6B are schematic sectional views showing an operation of the semiconductor device of the first embodiment.

The semiconductor device 1 includes the isolation region 103. The deep p⁺-type semiconductor region 36 is not provided in the isolation region 103 of the semiconductor device 1. The p-type semiconductor region 35 is provided in the isolation region 103 of the semiconductor device 1, and the semiconductor region 35 is in contact with the electrode 11. Furthermore, the collector region 25 and the cathode region 26 are separated from each other through the isolation region 103.

The distance between the IGBT region 101 and the FWD region 102 becomes large by providing the isolation region 103. Accordingly, as shown in FIG. 6A, when the PIN diode in the FWD region 102 is in the ON state, electrons (e) and holes (h) flowing from the FWD region 102 to the IGBT region 101 become liable to disappear on the way. Besides, even if holes (h2) flowing from the IGBT region 101 to the FWD region 102 are generated in the ON state of the PIN diode, the holes (h2) become liable to disappear on the way.

Furthermore, since the distance between the IGBT region 101 and the FWD region 102 becomes large, electrons (e3) are hard to move from the FWD region 102 to the IGBT region 101 in the recovery state of the PIN diode, then holes (h3) are hard to be generated. Besides, even if the electrons (e3) move from the FWD region 102 to the IGBT region 101 and the holes (h3) are generated, the holes (h3) flowing from the IGBT region 101 to the FWD region 102 are liable to disappear on the way.

Furthermore, the impurity concentration of the p-type semiconductor region 35 is lower than the impurity concentration of the p⁺-type anode region 32. Accordingly, the holes become hard to be injected into the third portion 20c of the semiconductor region 20 from the semiconductor region 35.

Furthermore, the semiconductor region 35 and the electrode 11 are electrically connected. Thus, at the recovery of the PIN diode, holes (h) existing under the semiconductor region 35 become liable to be discharged to the electrode 11 side through the semiconductor region 35 (FIG. 6B).

Furthermore, in the isolation region 103, the same negative potential as the electrode 11 (anode electrode) is applied to the connection region 54 at the recovery. Accordingly, the induced region where the hole concentration increases is induced along the insulating film 55 in the semiconductor region 35. Thus, holes are efficiently discharged also from the isolation region 103 to the electrode 11, the breakdown strength at the recovery increases.

As stated above, as compared with the semiconductor device 501, the recovery speed of the PIN diode further increases in the semiconductor device 1.

A simulation result in which carrier density at anode side decreases by providing the isolation region 103 will be described below.

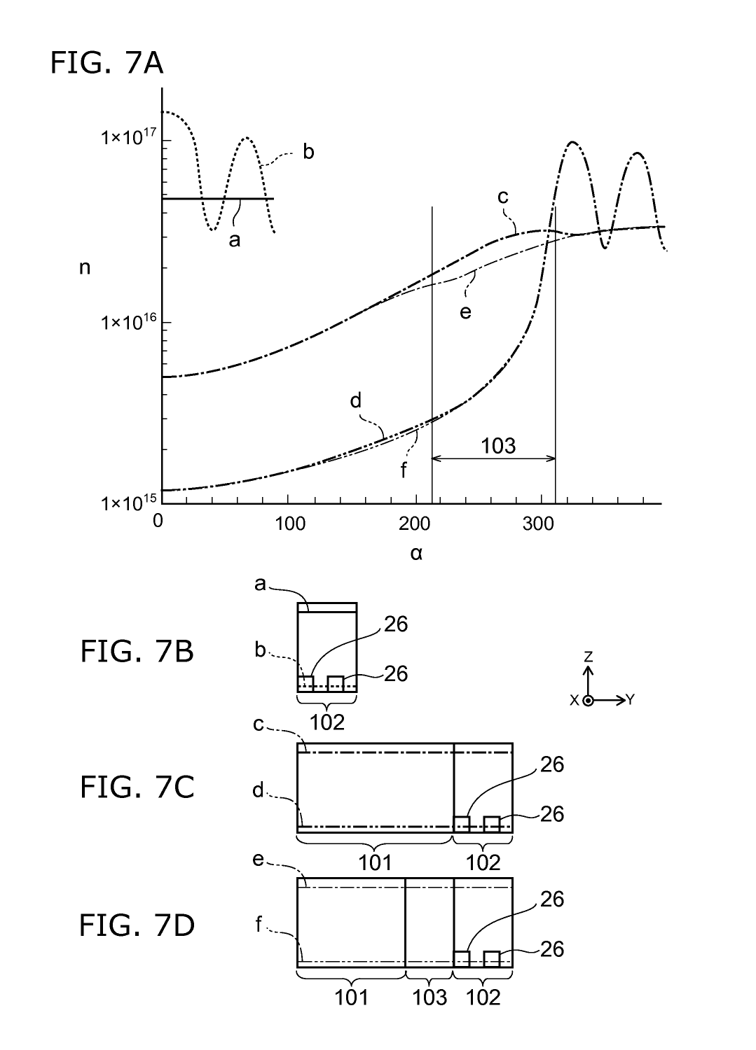

FIG. 7A is a graph showing an example of the simulation result of the carrier density at recovery in the semiconductor device, and FIG. 7B to FIG. 7D show models of the semiconductor devices used for the simulation shown in FIG. 7A.

The horizontal axis of FIG. 7A indicates distance d (μm) in the Y-direction of the semiconductor device, and the vertical axis indicates carrier density n (/cm³). FIG. 7A shows carrier densities at the anode sides and the cathode sides of the respective models. Here, the “anode sides” of FIG. 7A to FIG. 7D mean positions (lines (a), (c) and (e)) with a depth of 10 μm from the upper surfaces of the respective models, and the “cathode sides” mean positions (lines (b), (d) and (f)) with a depth of 10 μm from the lower surfaces of the respective models.

FIG. 7B shows the model in which the FWD region 102 in the semiconductor device is assumed. FIG. 7C shows the model (corresponding to the semiconductor device 500) in which the isolation region 103 is not provided. FIG. 7D shows the model in which the semiconductor device of the first embodiment is assumed. Incidentally, the cathode region 26 is separated in the Y-direction in the respective models. Furthermore, the width of the FWD region 102 in the Y-direction is 90 μm. The width of the IGBT region 101 of FIG. 7B in the Y-direction is 308 μm. The width of the IGBT region 101 of FIG. 7D in the Y-direction is 210 μm, and the width of the isolation region 103 in the Y-direction is 98 μm.

As is understood from FIG. 7A, the mode (line (a)) of the FWD region 102 shown in FIG. 7B is highest among the hole densities at the anode sides of the respective models. Next, in the model (line (c)) shown in FIG. 7C in which the isolation region 103 is not provided, and the IGBT region 101 and the FWD region 102 are connected, the hole density at the anode side is relatively low as compared with the model shown in FIG. 7B. Further, in the model (line (e)) shown in FIG. 7D in which the isolation region 103 is provided, the hole density in the isolation region 103 is lower than that of the model shown in FIG. 7C. That is, the hole density at the anode side is decreased by providing the isolation region 103.

Incidentally, the electron density at the cathode side of the semiconductor device is highest in the model (line (b)) shown in FIG. 7B. The electron density of the model (line (d)) shown in FIG. 7C and that of the model (line (e)) shown in FIG. 7D are relatively low as compared with that of the model shown in FIG. 7B. Incidentally, the electron density at the cathode side is not constant (waveform changes) in the lateral direction. This is because the cathode region 26 is divided, and an average value has only to be considered.

### Second Embodiment

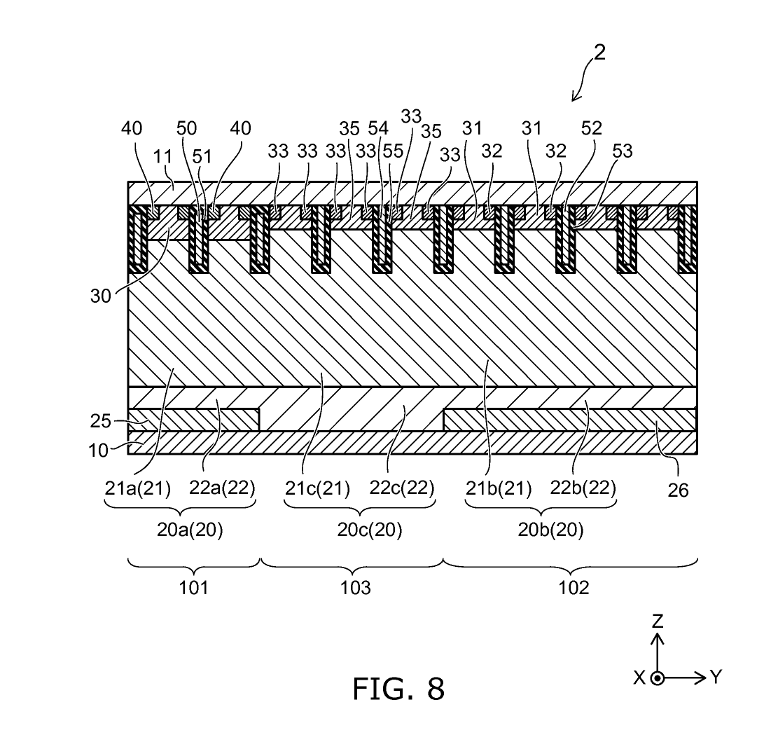

FIG. 8 is a schematic sectional view showing a semiconductor device of a second embodiment.

A semiconductor device 2 of the second embodiment further includes plural p⁺-type semiconductor region 33 (ninth semiconductor region) provided in an isolation region 103.

The semiconductor regions 33 are provided between an electrode 11 and a semiconductor region 35. The impurity concentration of the semiconductor region 33 is higher than the impurity concentration of the semiconductor region 35. That is, the semiconductor region 33 is a low resistance region for holes as compared with the semiconductor region 35. Accordingly, holes existing in the isolation region 103 are efficiently discharged to the electrode 11 through the semiconductor region 33 at recovery. Thus, the recovery speed of the semiconductor device 2 becomes high as compared with the recovery speed of the semiconductor device 1. Besides, since a hole injection amount can be increased during conduction, the on-voltage decreases.

### Third Embodiment

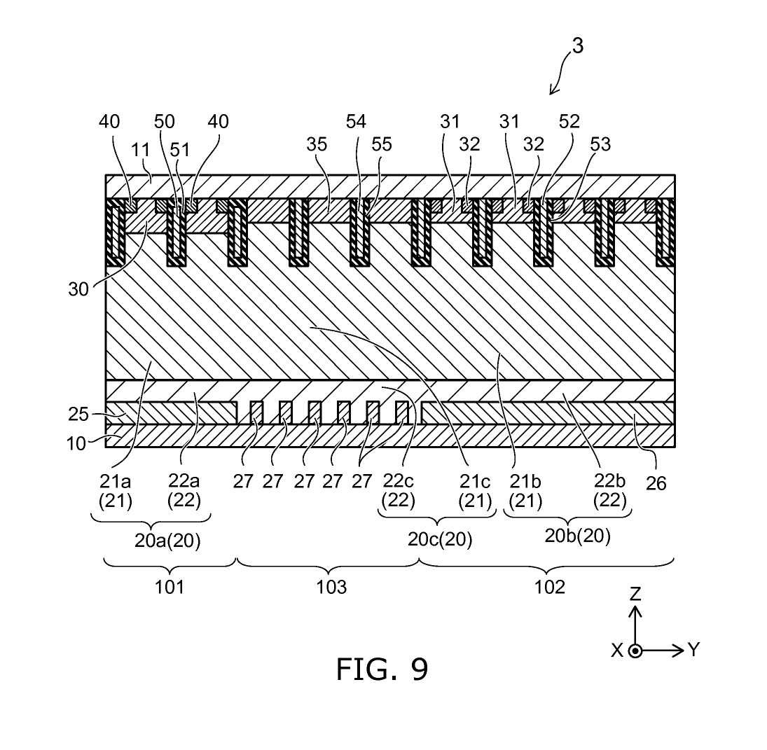

FIG. 9 is a schematic sectional view showing a semiconductor device of a third embodiment.

A semiconductor device 3 of the third embodiment further includes plural n⁺-type semiconductor regions 27 (tenth semiconductor region) in an isolation region 103.

The semiconductor regions 27 are provided between a third portion 20c of a semiconductor region 20 and an electrode 10. The impurity concentration of the semiconductor region 27 is higher than the impurity concentration of the semiconductor region 20. Thus, an electron injection amount from the n⁺-type semiconductor region 27 to the FWD region 102 increases. Thus, the on-voltage of the FWD region 102 of the semiconductor device 3 decreases as compared with the on-voltage of the semiconductor device 1.

### Fourth Embodiment

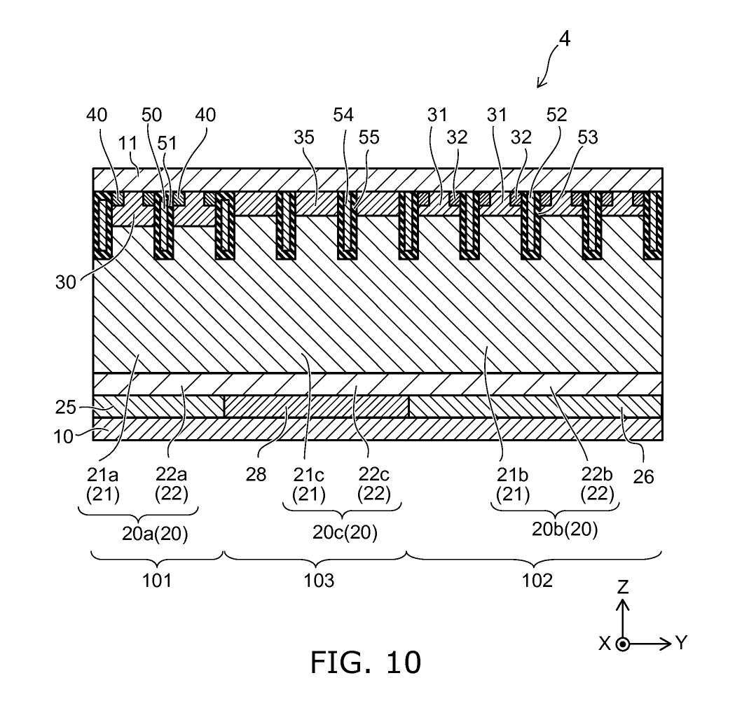

FIG. 10 is a schematic sectional view showing a semiconductor device of a fourth embodiment.

A semiconductor device 4 of the fourth embodiment further includes a p-type semiconductor region 28 (eleventh semiconductor region) in an isolation region 103.

The semiconductor region 28 is provided between a third portion 20c of a semiconductor region 20 and an electrode 10. The impurity concentration of the semiconductor region 28 is lower than the impurity concentration of a collector region 25. The p-type semiconductor region 28 is provided between the third portion 20c of the semiconductor region 20 and the electrode 10, so that injection of electrons from the electrode 10 side is further suppressed in the isolation region 103 at recovery. Thus, the recovery speed of the semiconductor device 4 becomes higher than the recovery speed of the semiconductor device 1.

### Fifth Embodiment

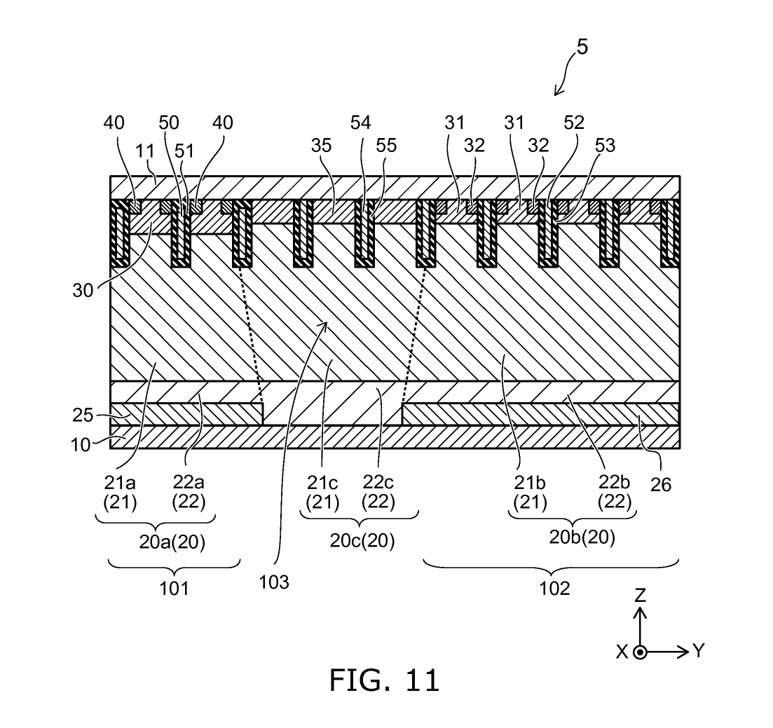

FIG. 11 is a schematic sectional view showing a semiconductor device of a fifth embodiment.

In a semiconductor device 5 of the fifth embodiment, the width of a set of connection regions 54, insulating films 55 and semiconductor regions 35, which are arranged in the Y-direction, is different from the width in the Y-direction of a portion 22c of a semiconductor region 22 sandwiched between a collector region 25 and a cathode region 26. Also in the structure, an isolation region 103 exists between an IGBT region 101 and a FWD region 102, and the same operation as that of the semiconductor device 1 is obtained.

### Sixth Embodiment

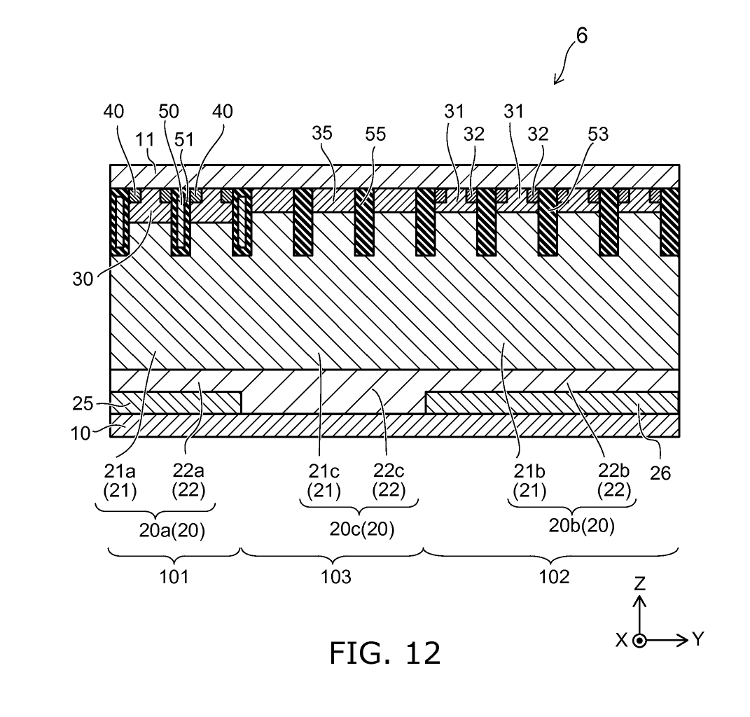

FIG. 12 is a schematic sectional view showing a semiconductor device of a sixth embodiment.

In a semiconductor device 6 of the sixth embodiment, the connection regions 52 and 54 are removed from the semiconductor device 1. That is, an insulating film 53 is in contact with an electrode 11 in a FWD region 102. Besides, the insulating film 53 is in contact with a second portion 20b of a semiconductor region 20 and anode regions 31 and 32. Besides, an insulating film 55 is in contact with the electrode 11 in an isolation region 103. The insulating film 55 is in contact with a third portion 20c of the semiconductor region 20 and a semiconductor region 35.

In this structure, an avalanche is liable to occur near respective lower ends of the insulating films 53 and 55. Thus, the breakdown strength of the semiconductor device 6 at recovery increases.

### Seventh Embodiment

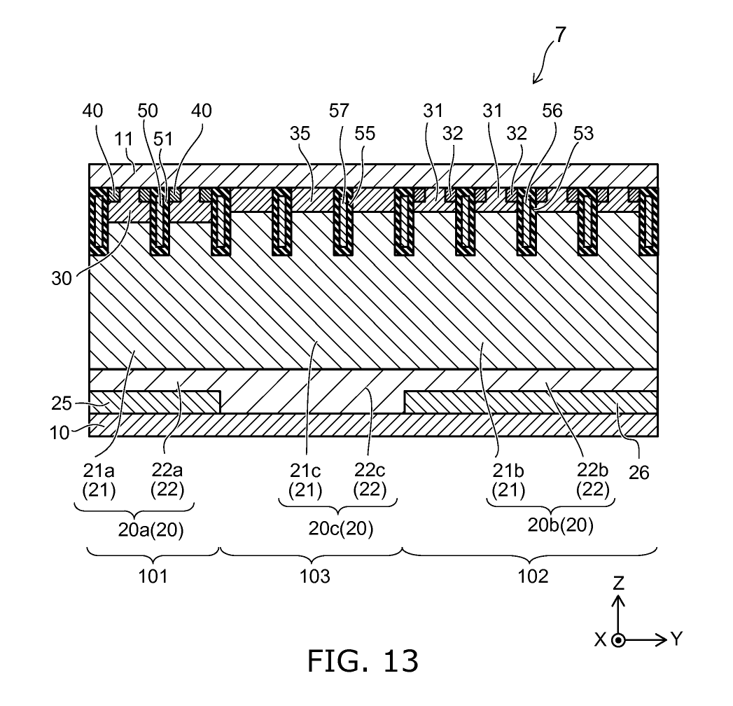

FIG. 13 is a schematic sectional view showing a semiconductor device of a seventh embodiment.

In a semiconductor device 7 of the seventh embodiment, an electrode 56 (fourth electrode) is provided in an insulating film 53 in a FWD region 102. The potential of the electrode 56 floats. Besides, in the semiconductor device 7, an electrode 57 (fifth electrode) is provided in an insulating film 55 in an isolation region 103. The potential of the electrode 57 floats.

In this structure, the potential of each of the electrodes 56 and 57 can be controlled independently of an electrode 11. For example, when a negative potential is applied to each of the electrodes 56 and 57, an induced region where hole concentration increases is induced along the insulating film 53 in an anode region 31, and an induced region where hole concentration increases is induced along the insulating film 55 in a semiconductor region 35. Thus, breakdown strength at recovery increases.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments.

The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments.

It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first electrode;
a second electrode; and
a first semiconductor region of a first conductivity-type provided between the first electrode and the second electrode,
the device including:
a first element region including
a second semiconductor of a second conductivity-type region provided between the first semiconductor region and the first electrode,
a third semiconductor region of the second conductivity-type provided between the first semiconductor region and the second electrode,
a fourth semiconductor region of the first conductivity-type provided between the third semiconductor region and the second electrode, and
a third electrode provided in the first semiconductor region, the third semiconductor region and the fourth semiconductor region via a first insulating film,
a second element region including
a fifth semiconductor region of the first conductivity-type provided between the first semiconductor region and the first electrode, and the fifth semiconductor region having a higher impurity concentration than the first semiconductor region, and
a sixth semiconductor region of the second conductivity-type provided between the first semiconductor region and the second electrode, and
an isolation region including a seventh semiconductor region of the second conductivity-type provided between the first semiconductor region and the second electrode, and the seventh semiconductor region being in contact with the second electrode, the isolation region being positioned between the first element region and the second element region.

2. The device according to claim 1, further comprising an eighth semiconductor region of the second conductivity-type provided between the second electrode and the sixth semiconductor region, and the eighth semiconductor region having a higher impurity concentration than the sixth semiconductor region.

3. The device according to claim 1, further comprising a ninth semiconductor region of the second conductivity-type provided between the second electrode and the seventh semiconductor region, and the ninth semiconductor region having a higher impurity concentration than the seventh semiconductor region.

4. The device according to claim 1, further comprising a tenth semiconductor region of the first conductivity-type provided between the first semiconductor region and the first electrode, and the tenth semiconductor region having a higher impurity concentration than the first semiconductor region.

5. The device according to claim 1, further comprising an eleventh semiconductor region of the second conductivity-type provided between the first semiconductor region and the first electrode.

6. The device according to claim 5, wherein
the eleventh semiconductor region is provided between the second semiconductor region and the fifth semiconductor region, and
the eleventh semiconductor region is in contact with the second semiconductor region and the fifth semiconductor region.

7. The device according to claim 1, further comprising a first connection region in contact with the second electrode,
the first connection region being in contact with the first semiconductor region and the sixth semiconductor region via a second insulating film.

8. The device according to claim 1, further comprising a second insulating film in contact with the second electrode,
the second insulating film being in contact with the first semiconductor region and the sixth semiconductor region.

9. The device according to claim 8, further comprising a fourth electrode in the second insulating film,
a potential of the fourth electrode being floating.

10. The device according to claim 1, further comprising a second connection region in contact with the second electrode,
the second connection region being in contact with the first semiconductor region and the seventh semiconductor region via a third insulating film.

11. The device according to claim 10, wherein a first length of a combination of the second connection region, the third insulating film and the seventh semiconductor region is different from a second length of the first semiconductor region,
the first semiconductor region is positioned between the second semiconductor region and the fifth semiconductor region,
the second connection region, the third insulating film and the seventh semiconductor region are positioned between the first element region and the second element region.

12. The device according to claim 11, wherein the second length is shorter than the first length.

13. The device according to claim 11, wherein a boundary between the second semiconductor region and the first semiconductor region is position below the seventh semiconductor region in a direction crossing a direction from the first electrode toward the second electrode.

14. The device according to claim 11, wherein a boundary between the fifth semiconductor region and the first semiconductor region is position below the seventh semiconductor region in a direction crossing a direction from the first electrode toward the second electrode.

15. The device according to claim 1, further comprising a third insulating film in contact with the second electrode,
the third insulating film being in contact with the first semiconductor region and the sixth semiconductor region.

16. The device according to claim 15, further comprising a fifth electrode in the third insulating film,
a potential of the fifth electrode being floating.

17. The device according to claim 1, wherein an impurity concentration of the seventh semiconductor region is lower than an impurity concentration of the sixth semiconductor region.

18. The device according to claim 1, wherein an impurity concentration of the third semiconductor region is higher than an impurity concentration of the sixth semiconductor region.

19. The device according to claim 1, wherein a distance between the first electrode and the sixth semiconductor region is equal to a distance between the first electrode and the seventh semiconductor region.
